(19) United States
(12) Patent Application Publication
(10) Pub. No.: US 2026/0282730 A1
(43) Pub. Date: Sep. 17, 2026

(54) DISPLAY DEVICE, DISPLAY DEVICE INSPECTION METHOD, AND DISPLAY DEVICE MANUFACTURING METHOD

(71) Applicant: Sharp Display Technology Corporation, Kameyama City, Mie (JP)

(72) Inventors: Masaki KOTANI, Kameyama City (JP); Masaki HIRUOKA, Kameyama City (JP)

(21) Appl. No.: 19/473,871

(22) PCT Filed: Apr. 12, 2023
(86) PCT No.: PCT/JP2023/014798

§ 371 Date: Oct. 9, 2025

(51) Int. Cl. H10K 59/88; G09G 3/00; H10K 59/12; H10K 59/122; H10K 59/80; H10K 71/70

(52) U.S. Cl. CPC H10K 59/88; G09G 3/006; H10K 59/1201; H10K 59/122; H10K 59/871; H10K 71/70; G09G 2330/12

(57) ABSTRACT

A display device includes a substrate, a plurality of light-emitting elements on the substrate, a bank portion surrounding the plurality of light-emitting elements, a sealing layer, and a dummy pattern. The sealing layer includes an organic material and covers the plurality of light-emitting elements. The dummy pattern is located between the sealing layer and the substrate and on a side opposite to the plurality of light-emitting elements with respect to the bank portion. The sealing layer has optical transparency, and the dummy pattern has light reflectivity.

### TECHNICAL FIELD

The disclosure relates to a display device including a plurality of light-emitting elements, an inspection method of a display device, and a manufacturing method of a display device.

### BACKGROUND ART

In a manufacturing method of a display device including a plurality of self-light-emitting elements on a substrate, a method of applying an organic material having optical transparency from above the self-light-emitting elements is known as a method of forming a sealing layer for sealing the self-light-emitting elements. In the application process of the organic material, it is necessary to detect a defect in which the applied organic material flows out from a predetermined position of the substrate to the peripheral side. JP 2013-222529 A describes a technique of applying ink to a substrate having a groove portion and detecting the groove portion where the ink overflows.

### SUMMARY

### Technical Field

In the detection method described in JP 2013-222529 A, the groove portion where the ink overflows is detected by performing an appearance inspection using a microscope or the like. Here, the organic material used for the sealing layer has optical transparency. Therefore, in a case where the defect of the overflow of the sealing layer described above is detected by a method of directly observing the applied material as in the detection method described in JP 2013-222529 A, when the intensity of the light source used at the time of observation is low, it is difficult to visually observe the sealing layer, and thus, it is difficult to perform the defect inspection.

A display device according to an aspect of the disclosure includes a substrate, a plurality of light-emitting elements formed on the substrate, a bank portion formed on the substrate and surrounding the plurality of light-emitting elements, a light-transmissive sealing layer including an organic material and covering the plurality of light-emitting elements, and a dummy pattern having light reflectivity between the sealing layer and the substrate and on a side opposite to the plurality of light-emitting elements with respect to the bank portion.

A manufacturing method of a display device according to an aspect of the disclosure includes: preparing a substrate; forming a dummy pattern having light reflectivity on the substrate; after the dummy pattern is formed, forming a plurality of light-emitting elements and a bank portion surrounding the plurality of light-emitting elements on the substrate; and after the plurality of light-emitting elements and the bank portion are formed, forming a light-transmissive sealing layer covering the light-emitting elements, in which the forming the sealing layer includes applying an organic material.

### Advantageous Effects of Disclosure

To facilitate inspection of the presence or absence of an organic material at a predetermined position.

### BRIEF DESCRIPTION OF DRAWINGS

FIG. 1 includes schematic cross-sectional views of a display device according to an embodiment.

FIG. 2 is a schematic plan view of the display device according to the embodiment.

FIG. 3 is an enlarged plan view of the display device according to the embodiment.

FIG. 4 is a flowchart illustrating a manufacturing method of the display device according to the embodiment.

FIG. 5 is a flowchart illustrating a method of forming a thin film transistor layer according to the embodiment.

FIG. 6 is a flowchart illustrating a method of forming a light-emitting element layer according to the embodiment.

FIG. 7 is a flowchart illustrating a method of forming a sealing layer according to the embodiment.

FIG. 8 is an enlarged plan view of a defective display device for describing an inspection method of the display device according to the embodiment.

### DESCRIPTION OF EMBODIMENTS

### Embodiments

### Display Device: Overview

Embodiments of the disclosure will be described below with reference to the drawings. In each drawing, the same components are denoted by the same reference numerals and signs, and a description thereof is omitted.

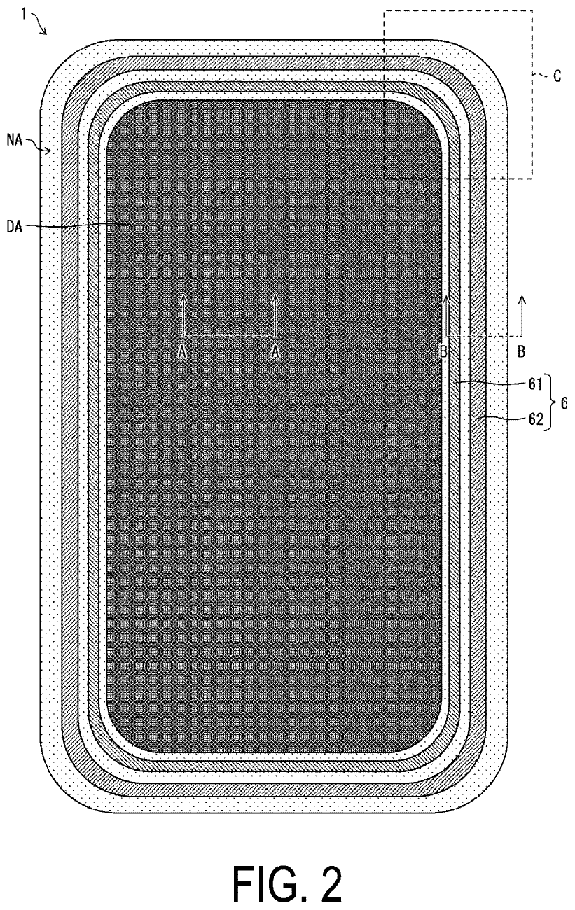

FIG. 2 is a schematic plan view of a display device according to the present embodiment. In FIG. 2, a bank portion 6 described below is extracted and illustrated.

The display device 1 is a device that can be used as a display of, for example, a television, a smartphone, or the like. The display device 1 includes a display portion DA and a frame portion NA formed around the display portion DA. The display device 1 performs display in the display portion DA by controlling light emission from each of a plurality of light-emitting elements, which will be described below, formed in the display portion DA. In the frame portion NA, a driver or the like for driving each of the plurality of light-emitting elements of the display portion DA may be formed.

The display portion DA of the display device 1 according to the present embodiment may include a plurality of subpixels including red subpixels, green subpixels, and blue subpixels. A light-emitting element, which will be described below, is formed in each subpixel, and each light-emitting element individually emits light. Thus, the display device 1 performs display by individually controlling light emission from the plurality of light-emitting elements of the display portion DA by using, for example, a driver or the like formed in the frame portion NA.

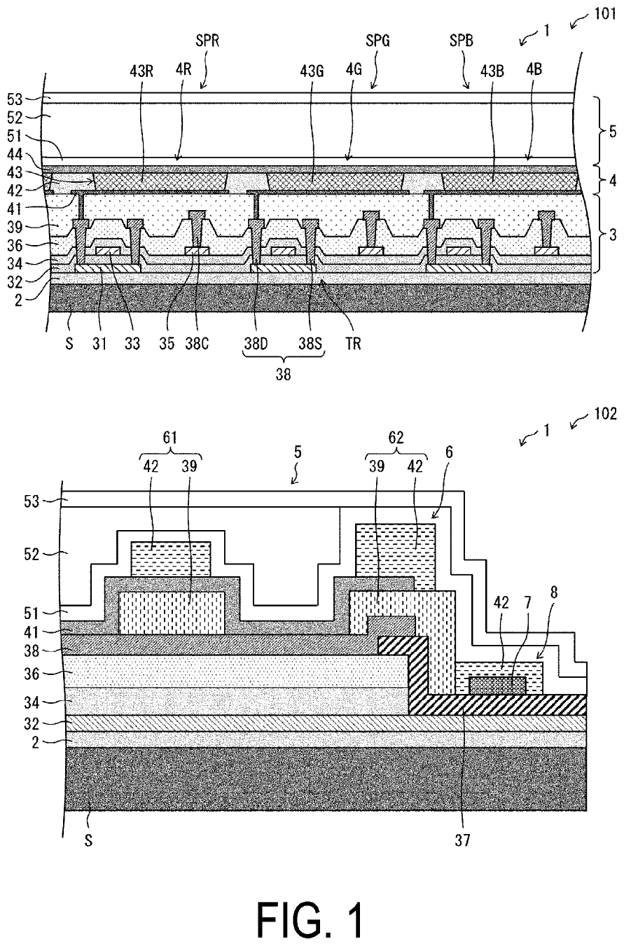

The display device 1 according to the present embodiment will be described in detail with reference to FIG. 1. FIG. 1 includes schematic cross-sectional views of the display device 1 according to the present embodiment. In particular, a schematic cross-sectional view 101 of FIG. 1 is a cross-sectional view taken along line A-A in FIG. 2, and is a schematic cross-sectional view illustrating particularly a cross section passing through a red subpixel SPR, a green subpixel SPG, and a blue subpixel SPB, which will be described below, of the display portion DA of the display device 1. A schematic cross-sectional view 102 of FIG. 1 is a cross-sectional view taken along line B-B in FIG. 2, in other words, a schematic cross-sectional view illustrating a cross section passing from the display portion DA side to the peripheral side of the display device 1, of the frame portion NA of the display device 1.

The display device 1 according to the present embodiment includes a substrate S formed over the display portion DA and the frame portion NA. Further, the display device 1 includes a base coat layer 2, a thin film transistor layer 3, a light-emitting element layer 4, and a sealing layer 5 on the substrate S in this order.

In particular, the display device 1 includes the substrate S to the thin film transistor layer 3 as an underlayer substrate, and includes a plurality of light-emitting elements in the light-emitting element layer 4 on the underlayer substrate. In the display device 1, the plurality of light-emitting elements are sealed between the sealing layer 5 and the underlayer substrate by the sealing layer 5.

In the present embodiment, the display device 1 includes, as a subpixel, a plurality of red subpixels SPR, a plurality of green subpixels SPG, and a plurality of blue subpixels SPB, arrayed in the display portion DA in a plan view. The red subpixel SPR, the green subpixel SPG, and the blue subpixel SPB are formed with a red light-emitting element 4R, a green light-emitting element 4G, and a blue light-emitting element 4B, respectively, which are included in the light-emitting element layer 4.

### Display Device: Underlayer Substrate

Hereinafter, each layer of the display device 1 will be described in greater detail.

The substrate S may be, for example, a rigid substrate such as a glass substrate, or may be a substrate having flexibility such as a resin substrate containing polyethylene terephthalate (PET). When the substrate S has flexibility, the display device 1 may be a flexible display device having flexibility.

The base coat layer 2 is a layer that prevents moisture or impurities infiltrated from the substrate S side from reaching the thin film transistor layer 3 or the light-emitting element layer 4 when the display device 1 is used. The base coat layer 2 can be formed of a silicon oxide (SiOₓ) film or a silicon nitride (SiNₓ) film, or a layered film thereof, for example. From the viewpoint of reducing infiltration of moisture or impurities, the base coat layer 2 may be formed up to the edge portion side of the display device 1 of the frame portion NA.

The thin film transistor layer 3 includes a semiconductor layer 31, a gate insulating film 32, a gate electrode 33, a first interlayer film 34, a capacitance electrode 35, a second interlayer film 36, an auxiliary interlayer film 37, a source electrode layer 38, and a flattening film 39 in order from the base coat layer 2 side.

The semiconductor layer 31 is formed on the base coat layer 2, and is formed in island shapes for each subpixel. The semiconductor layer 31 may include, for example, a source region, a drain region, and a channel region located between the source region and the drain region. The semiconductor layer 31 may contain low-temperature polysilicon (LTPS) or a semiconductor such as an oxide semiconductor.

The gate insulating film 32 is an inorganic insulating film formed on the base coat layer 2 and the semiconductor layer 31. The gate insulating film 32 may be formed up to the edge portion side of the display device 1 of the frame portion NA.

The gate electrode 33 is formed on the gate insulating film 32, and particularly, is formed at a position facing the channel region of the semiconductor layer 31 of each subpixel with the gate insulating film 32 interposed therebetween. The gate electrode 33 may be electrically insulated from the semiconductor layer 31 by the gate insulating film 32, and may be electrically connected to a gate driver of the display device 1 via a gate signal line (not shown) and driven by the gate driver.

The first interlayer film 34 is an inorganic film formed on the gate insulating film 32 and the gate electrode 33. The capacitance electrode 35 is formed on the first interlayer film 34, and particularly, is formed in island shapes on a subpixel-by-subpixel basis. The second interlayer film 36 is an inorganic film formed on the first interlayer film 34 and the capacitance electrode 35. The first interlayer film 34 and the second interlayer film 36 may be formed up to the middle of the frame portion NA in a direction from the center side to the peripheral side of the display device 1.

The auxiliary interlayer film 37 is formed in the frame portion NA, and is formed, for example, on the gate insulating film 32 and on the peripheral edge portion of the second interlayer film 36. The auxiliary interlayer film 37 covers the end faces of the first interlayer film 34 and the second interlayer film 36 on the frame portion NA side. The auxiliary interlayer film 37 may be formed up to the edge portion side of the display device 1 of the frame portion NA. Note that the auxiliary interlayer film 37 may be formed also in the display portion DA.

The source electrode layer 38 is formed in island shapes in the display portion DA, and particularly includes a source electrode 38S electrically connected to the source region of the semiconductor layer 31 and a drain electrode 38D electrically connected to the drain region of the semiconductor layer 31. The source electrode 38S and the drain electrode 38D are each electrically connected to the semiconductor layer 31 via a contact hole formed in the gate insulating film 32, the first interlayer film 34, and the second interlayer film 36. The source electrode layer 38 may include an auxiliary capacitance electrode 38C in island shapes electrically connected to the capacitance electrode 35. The source electrode layer 38 may be extended to the frame portion NA, or may form a part of an auxiliary electrode connected to a power supply (not shown). In the frame portion NA, the source electrode layer 38 may be formed on the second interlayer film 36 and on the edge portion of the auxiliary interlayer film 37 on the display portion DA side.

The thin film transistor layer 3 includes a thin film transistor TR including the semiconductor layer 31, the gate electrode 33, the capacitance electrode 35, the source electrode 38S, and the drain electrode 38D, on a subpixel-by-subpixel basis. Note that the thin film transistor layer 3 includes the top gate thin film transistor TR including the gate electrode 33 in an upper layer of the semiconductor layer 31, but is not limited thereto, and may include a bottom gate thin film transistor TR including the gate electrode 33 in a lower layer of the semiconductor layer 31.

The flattening film 39 is formed on the second interlayer film 36 and the source electrode layer 38 in the display portion DA, and has a function of flattening the upper surface of the thin film transistor layer 3. In the present embodiment, the flattening film 39 is also formed in the frame portion NA, and forms a part of each of a first bank 61 and a second bank 62 described below.

The gate insulating film 32, the first interlayer film 34, the second interlayer film 36, and the auxiliary interlayer film 37 each can be formed of a silicon oxide (SiOx) film or a silicon nitride (SiNx) film, or a layered film thereof. The gate electrode 33, the capacitance electrode 35, and the source electrode layer 38 may include, for example, at least one of aluminum (Al), tungsten (W), molybdenum (Mo), tantalum (Ta), chromium (Cr), titanium (Ti), and copper (Cu). The gate electrode 33, the capacitance electrode 35, and the source electrode layer 38 may be formed by a single-layer film or a layered film of any of the metals described above. The flattening film 39 can be formed of, for example, a coatable organic material such as polyimide and acrylic.

### Display Device: Light-Emitting Element Layer

The light-emitting element layer 4 includes an anode 41 as a first electrode, an edge cover 42, a light-emitting layer 43, and a cathode 44 as a second electrode, in this order from the thin film transistor layer 3 side.

The anode 41 is formed on the flattening film 39 in the display portion DA, and is formed in island shapes for each subpixel. Each anode 41 is electrically connected to the drain electrode 38D formed in each subpixel via a contact hole formed in the flattening film 39. The anode 41 may be extended to the frame portion NA, or may form a part of the auxiliary electrode described above. In the frame portion NA, the anode 41 may be formed on the source electrode layer 38 and the flattening film 39.

The edge cover 42 is formed on the flattening film 39 and on the peripheral edge portion of each anode 41 in the display portion DA, and has a function of preventing a short circuit between the light-emitting elements respectively formed in the subpixels adjacent to each other. The edge cover 42 has a function of reducing the influence of electric field concentration at the peripheral edge portion of each anode 41 on the driving of each light-emitting element. In the present embodiment, the edge cover 42 is also formed in the frame portion NA. The edge cover 42 forms a part of each of the first bank 61 and the second bank 62 described below, and an auxiliary bank portion 8 described below.

The light-emitting layer 43 is formed in island shapes on each anode 41. The light-emitting layer 43 includes a red light-emitting layer 43R located in the red subpixel SPR, a green light-emitting layer 43G located in the green subpixel SPG, and a blue light-emitting layer 43B located in the blue subpixel SPB.

The cathode 44 is formed on the edge cover 42 and the light-emitting layer 43, and particularly, is formed in common to a plurality of subpixels.

The anode 41 may be formed by layering, for example, indium tin oxide (ITO) and an alloy containing Ag, and may have light reflectivity. The cathode 44 may be formed by a conductive material having optical transparency such as indium tin oxide (ITO) and indium zincum oxide (IZO). The light-emitting layer 43 may include an organic light-emitting material or an inorganic light-emitting material such as quantum dots, which is excited by excitons generated by recombination of holes from the anode 41 and electrons from the cathode 44 described below to emit light.

The light-emitting element layer 4 includes the red light-emitting element 4R including the anode 41, the red light-emitting layer 43R, and the cathode 44 for each red subpixel SPR. The light-emitting element layer 4 includes the green light-emitting element 4G including the anode 41, the green light-emitting layer 43G, and the cathode 44 for each green subpixel SPG. Further, the light-emitting element layer 4 includes the blue light-emitting element 4B including the anode 41, the blue light-emitting layer 43B, and the cathode 44 for each blue subpixel SPB. Therefore, the display device 1 includes, in the light-emitting element layer 4, a plurality of light-emitting elements each including two electrodes including the anode 41 and the cathode 44 and the light-emitting layer 43 between the two electrodes, on a subpixel-by-subpixel basis.

The display device 1 controls the voltage applied to the gate electrode 33 via the thin film transistor TR, and controls the amount of current flowing from the source electrode 38S to the drain electrode 38D via the semiconductor layer 31. Thus, the display device 1 individually controls the voltage applied to each anode 41 via each thin film transistor TR. On the other hand, the display device 1 applies a substantially constant voltage to the cathode 44.

In particular, the display device 1 applies a voltage to each anode 41 to make the potential of the anode 41 higher than the potential of the cathode 44, thereby driving each light-emitting element. In the driven light-emitting element, holes are injected from the anode 41 and electrons are injected from the cathode 44 toward the light-emitting layer 43. The holes and electrons injected into the light-emitting layer 43 recombine to generate excitons, and the light-emitting material contained in the light-emitting layer 43 is excited, whereby the light-emitting layer 43 emits light. In the display device 1, for example, light from the light-emitting layer 43 is extracted from the cathode 44 side, which is a transmissive electrode. As described above, the display device 1 individually controls light emission from each of the light-emitting elements including the red light-emitting element 4R, the green light-emitting element 4G, and the blue light-emitting element 4B.

By driving via the thin film transistor TR, red light is emitted from the red light-emitting layer 43R of the red light-emitting element 4R, green light is emitted from the green light-emitting layer 43G of the green light-emitting element 4G, and blue light is emitted from the blue light-emitting layer 43B of the blue light-emitting element 4B. Thus, the display device 1 performs full-color display of an image by the red light from each red subpixel SPR, the green light from each green subpixel SPG, and the blue light from each blue subpixel SPB.

Note that in the present embodiment, the “blue light” refers to, for example, light having a light emission central wavelength in a wavelength band equal to or more than 380 nm and equal to or less than 500 nm. The green light refers to, for example, light having a light emission central wavelength in a wavelength band greater than 500 nm and 600 nm or less. Furthermore, the red light is light having a light emission central wavelength in a wavelength band larger than 600 nm and equal to or less than 780 nm.

In the present embodiment, the light-emitting element layer 4 includes the anode 41 on the substrate S side, but is not limited thereto, and may include the cathode 44, the edge cover 42, the light-emitting layer 43, and the anode 41 in this order from the thin film transistor layer 3 side. In this case, the cathode 44 may be formed into island shapes on a subpixel-by-subpixel basis, and the anode 41 may be formed in common to the plurality of subpixels.

The light-emitting element layer 4 includes a top-emitting light-emitting element having the cathode 44 as a transmissive electrode, but is not limited thereto, and may include a bottom-emitting light-emitting element having the anode 41 as a transmissive electrode and extracting light emission from the anode 41 side.

The light-emitting element layer 4 may further include a hole injection layer, a hole transport layer, an electron blocking layer, and the like in this order from the anode 41 side between the anode 41 and the light-emitting layer 43. The light-emitting element layer 4 may further include a hole blocking layer, an electron transport layer, an electron injection layer, and the like in this order from the light-emitting layer 43 side between the cathode 44 and the light-emitting layer 43.

Display Device: Sealing Layer The sealing layer 5 includes a first inorganic layer 51, an organic layer 52, and a second inorganic layer 53 in order from the light-emitting element layer 4 side. The first inorganic layer 51 covers the cathode 44, the organic layer 52 is formed on the first inorganic layer 51, and the second inorganic layer 53 covers the first inorganic layer 51. Therefore, the sealing layer 5 is formed at a position covering the plurality of light-emitting elements of the light-emitting element layer 4.

Each layer of the sealing layer 5 is made of a light-transmissive material. In particular, the first inorganic layer 51 and the second inorganic layer 53 contain an inorganic material, and can be formed of a silicon oxide (SiOₓ) film or a silicon nitride (SiNₓ) film or a layered film thereof. The organic layer 52 can be formed of a coatable organic material, such as polyimide and acrylic, for example.

The first inorganic layer 51 and the second inorganic layer 53 are layers that prevent moisture or impurities infiltrated from the sealing layer 5 side from reaching the light-emitting element layer 4 or the thin film transistor layer 3. From the viewpoint of reducing infiltration of moisture or impurities, the first inorganic layer 51 and the second inorganic layer 53 may be formed up to the edge portion side of the display device 1 of the frame portion NA. For the same reason, the first inorganic layer 51 and the second inorganic layer 53 may be in contact with each other in the frame portion NA.

The organic layer 52 has a function of a buffer layer for reducing damage to the first inorganic layer 51 or the second inorganic layer 53 due to foreign matters when the foreign matters are mixed on the cathode 44, the first inorganic layer 51, or the like in a manufacturing process of the sealing layer 5. The sealing layer 5 includes two inorganic layers, namely, the first inorganic layer 51 and the second inorganic layer 53, and the organic layer 52 between the two inorganic layers, and thus more reliably reduces infiltration of moisture or impurities from the display surface side of the display device 1. The organic layer 52 may be formed over the display portion DA to the front side of the second bank 62 in the frame portion NA by a manufacturing method described below.

The display device 1 may further include an anti-reflection film, a touch panel film, and the like on the sealing layer 5.

### Display Device: Bank Portion

The display device 1 further includes the bank portion 6 in the frame portion NA. As illustrated in FIG. 2, the bank portion 6 is formed at a position surrounding the display portion DA in the frame portion NA in a plan view of the display device 1. In other words, the bank portion 6 is formed on the substrate S and is formed at a position surrounding the plurality of light-emitting elements included in the light-emitting element layer 4.

The bank portion 6 includes the first bank 61 and the second bank 62 located closer to the peripheral edge portion of the display device 1 than the first bank 61. Each of the first bank 61 and the second bank 62 may be formed by a part of the flattening film 39 and a part of the edge cover 42. The height of the second bank 62 from the upper surface of the substrate S may be higher than the height of the first bank 61 from the upper surface of the substrate S. Note that the specific configuration of the bank portion 6 is not limited to the above as long as at least a part of the bank portion 6 is formed at a position surrounding the light-emitting element of the display device 1 in a plan view of the display device 1. For example, the bank portion 6 may include only one of the first bank 61 and the second bank 62, or may further include a bank closer to the peripheral side of the display device 1 than the second bank 62.

The bank portion 6 has a function of restricting the organic layer 52, which is formed by coating by a method described below, from overflowing to the peripheral side from the peripheral edge portion of the substrate S. In the present embodiment, when the organic layer 52 is formed on the peripheral side of the substrate S with respect to the second bank 62, the display device 1 including the organic layer 52 is determined to be defective. Note that the organic layer 52 may be formed to cover the display portion DA and not to be formed on the peripheral side of the substrate S with respect to the second bank 62, and may be formed, for example, to a position between the first bank 61 and the second bank 62 or to a position in front of the first bank 61.

### Display Device: Dummy Pattern

The display device 1 includes a dummy pattern 7 in the frame portion NA. The dummy pattern 7 is located closer to the peripheral edge portion of the display device 1 than the bank portion 6, in other words, located on the opposite side of the plurality of light-emitting elements included in the light-emitting element layer 4 with respect to the bank portion 6. The dummy pattern 7 is formed between the substrate S and the sealing layer 5, for example, on the auxiliary interlayer film 37. However, the disclosure is not limited to this, and the dummy pattern 7 may be formed in a layer lower than the auxiliary interlayer film 37.

The dummy pattern 7 has light reflectivity. The dummy pattern 7 may reflect visible light having any wavelengths in a range from, for example, 380 nm to 780 nm. The dummy pattern 7 may include, for example, a metal material, and may be formed of a single-layer film or a multilayer film including at least one of a group including Ti, Mo, Al, and Cu. Accordingly, the display device 1 achieves the dummy pattern 7 having light reflectivity with a simpler configuration or at lower cost.

However, the dummy pattern 7 is not limited to this as long as the dummy pattern 7 has light reflectivity, and the dummy pattern 7 may include a semiconductor such as silicon. The light reflected by the dummy pattern 7 is not limited to visible light, and the dummy pattern 7 may reflect, for example, near-infrared light or near-ultraviolet light.

The dummy pattern 7 may be in the same layer as any of the electrodes of the thin film transistor layer 3, or may be in the same layer as the electrode having light reflectivity among the electrodes of the light-emitting element layer 4. For example, the dummy pattern 7 may be in the same layer as any electrode of the thin film transistor TR including the gate electrode 33, the capacitance electrode 35, and the source electrode layer 38 of the thin film transistor layer 3. Alternatively, the dummy pattern 7 may be in the same layer as the anode 41 of the light-emitting element layer 4.

In general, all the electrodes of the thin film transistor TR contain a metal material and often have light reflectivity. Therefore, when the dummy pattern 7 is in the same layer as any of the electrodes of the thin film transistor layer 3, in the manufacturing method of the display device 1, the dummy pattern 7 having light reflectivity can be formed by using a part of the process of forming the thin film transistor TR, and the manufacturing method is simplified. Similarly, when the dummy pattern 7 is in the same layer as the electrode having light reflectivity among the electrodes of the light-emitting element layer 4, in the manufacturing method of the display device 1, the dummy pattern 7 having light reflectivity can be formed by using a part of the process of forming the light-emitting element layer 4, and the manufacturing method is simplified.

Note that in the present specification, the expression “two members are in the same layer” means that the two members are formed in the same process and contain the same material. The dummy pattern 7 may include a plurality of electrodes formed in different processes in a layered manner.

The display device 1 includes an auxiliary bank portion 8 in the frame portion NA. The auxiliary bank portion 8 is formed at a position covering the dummy pattern 7, and has a function of reducing corrosion of the dummy pattern 7. The auxiliary bank portion 8 may be a part of the edge cover 42, in other words, may be in the same layer as at least a part of the bank portion 6. When the auxiliary bank portion 8 is in the same layer as at least a part of the bank portion 6, in the manufacturing method of the display device 1, the auxiliary bank portion 8 can be formed by using a part of the process of forming the bank portion 6, and the manufacturing method is simplified.

### Display Device: Positional Relationship between Bank Portion and Dummy Pattern

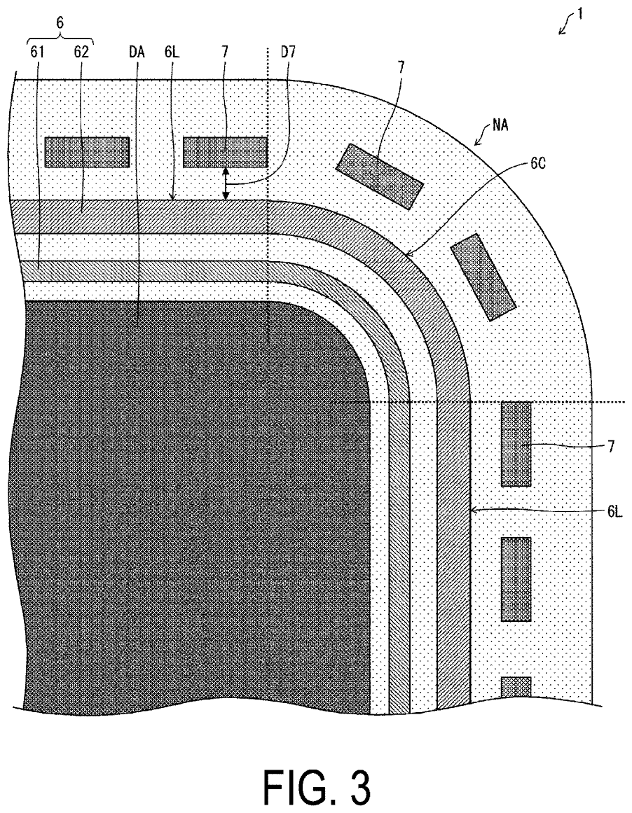

The formation position of the dummy pattern 7 and the positional relationship between the bank portion 6 and the dummy pattern 7 will be described in more detail with reference to FIG. 3. FIG. 3 is an enlarged plan view illustrating a portion of the display device 1 in an enlarged manner in a plan view. In particular, FIG. 3 illustrates an enlarged view of a region C illustrated in FIG. 2, in other words, illustrates the vicinity of a corner of the display device 1. In FIG. 3, the bank portion 6 and the dummy pattern 7 are extracted and illustrated.

As illustrated in FIG. 3, the display device 1 may have a curved line at the outer edge portion of the corner in a plan view, and accordingly, the bank portion 6 may also have a portion formed along the curved line in a plan view in the vicinity of the corner of the display device 1. In particular, the bank portion 6 includes two straight portions 6L along the respective sides of the display portion DA having a rectangular shape, and a curved portion 6C that connects the two straight portions 6L and is formed along the curved line in a plan view of the display device 1. The bank portion 6 may include, for example, four straight portions 6L formed along the respective sides of the display portion DA and four curved portions 6C formed in the vicinity of the respective corners of the display device 1. Note that in FIG. 3, the boundary between the straight portion 6L and the curved portion 6C is indicated by a dotted line. In this case, the dummy pattern 7 may be provided adjacent to each curved portion 6C and the two straight portions 6L on the curved portion 6C side, which are connected via the curved portion 6C.

A plurality of dummy patterns 7 may be formed in island shapes. When the dummy patterns 7 are formed in island shapes, the auxiliary bank portions 8 exhibit a function of preventing corrosion of the dummy patterns 7, being located in island shapes, only at positions covering the respective dummy patterns 7. Therefore, by providing the dummy patterns 7 in island shapes, the display device 1 does not need to form a series of the auxiliary bank portions 8 at positions surrounding the dummy patterns 7 in a plan view of the display device 1, for example, and the auxiliary bank portions 8 are provided with a simpler configuration. Further, by providing the dummy patterns 7 in island shapes, the display device 1 achieves simplification of the manufacturing process of the auxiliary bank portion 8 or reduction of the manufacturing cost.

At least a part of the dummy pattern 7 may be formed linearly along the bank portion 6. Further, in a plan view of the display device 1, when a distance between any portion of the bank portion 6 and any dummy pattern 7 is defined as a D7, the display device 1 may have a portion where the distance D7 is 30 μm or less.

However, the disclosure is not limited to this, and the display device 1 may have a portion where the distance between the bank portion 6 and the dummy pattern 7 is larger than 30 μm in a plan view of the display device 1. In particular, the dummy pattern 7 may be formed between the peripheral edge portion of the second bank 62 and the peripheral edge portion of the second inorganic layer 53 in a plan view of the display device 1. The distance between the peripheral edge portion of the second bank 62 and the peripheral edge portion of the second inorganic layer 53 in a plan view of the display device 1 may be about 150 μm. In this case, the dummy pattern 7 may be formed at a position where the distance from the second bank 62 is within 150 μm in a plan view of the display device 1.

### Manufacturing Method of Display Device: Up to Forming Base Coat Layer

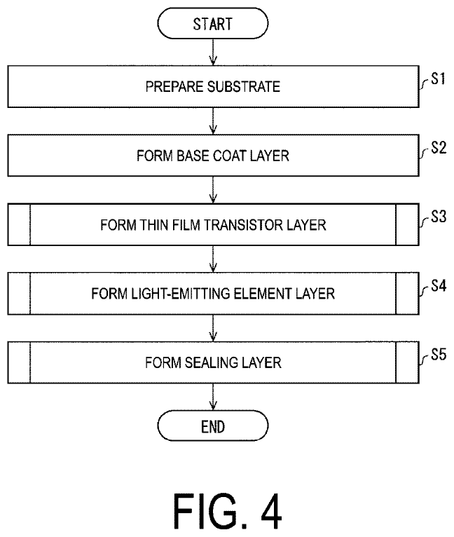

A manufacturing method of the display device 1 according to the present embodiment will be described with reference to FIG. 4. FIG. 4 is a flowchart illustrating the manufacturing method of the display device 1 according to the present embodiment.

In the manufacturing method of the display device 1, first, the substrate S is prepared (step S1). The step S1 may be performed by preparing, for example, a glass substrate, a film substrate, or the like. For example, a large-sized substrate S may be prepared in the step S1, and in this case, in the manufacturing method of the display device 1, after each layer is formed on the substrate S, a plurality of display devices 1 may be manufactured at a time by dividing the substrate S. In the step S1, a film substrate may be formed on a glass substrate as the substrate S. In this case, in the manufacturing method of the display device 1, after the layers are formed on the substrate S, the glass substrate may be peeled off from the substrate S to manufacture the display device 1 having flexibility.

Subsequently, the base coat layer 2 is formed on the substrate S (step S2). The step S2 may be performed by forming a film of the material of the base coat layer 2 on the substrate S by CVD, sputtering, or the like.

### Manufacturing Method of Display Device: Forming Thin Film Transistor Layer

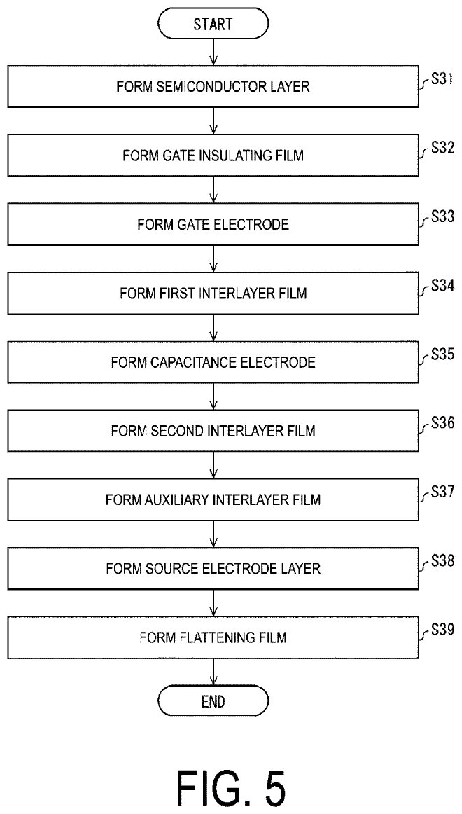

Subsequently, the thin film transistor layer 3 is formed on the base coat layer 2 (step S3). The process of forming the thin film transistor layer 3 will be described in more detail with reference to FIG. 5. FIG. 5 is a flowchart illustrating the process of forming the thin film transistor layer 3.

In the process of forming the thin film transistor layer 3, first, the semiconductor layer 31 is formed (step S31). The step S31 may be performed by, for example, forming a film containing a semiconductor material by CVD, sputtering, or the like, and then patterning the film by etching or the like. In the step S31, the semiconductor material may be crystallized by irradiating the thin film of the semiconductor material with laser light. In the step S31, a source region, a drain region, and a channel region between the source region and the drain region may be formed in the semiconductor layer 31 by doping or the like with respect to a film containing a semiconductor material.

Subsequently, the gate insulating film 32 is formed (step S32). The step S32 may be performed by forming a thin film of an inorganic material at a position covering the semiconductor layer 31 by CVD, sputtering, or the like.

Subsequently, the gate electrode 33 is formed (step S33). The step S33 may be performed by, for example, forming a thin film containing a metal material by CVD, sputtering, or the like, and then patterning the thin film by etching or the like.

Subsequently, the first interlayer film 34 is formed (step S34). The step S34 may be performed by forming a thin film of an inorganic material at a position covering the gate electrodes 33 by the same method as the step S32. Subsequently, the capacitance electrode 35 is formed (step S35). The step S35 may be performed by the same method as the step S33. Subsequently, the second interlayer film 36 is formed (step S36). The step S36 may be performed by forming a thin film of an inorganic material at a position covering the capacitance electrode 35 by the same method as the step S34. Subsequently, the auxiliary interlayer film 37 is formed (step S37). The step S37 may be performed by forming a thin film of an inorganic material by the same method as the step S32 and then patterning the thin film by an etching method or the like so that the thin film remains in the frame portion NA.

Subsequently, the source electrode layer 38 is formed (step S38). In the step S38, contact holes may be formed by an etching method or the like in portions of the first interlayer film 34 and the second interlayer film 36 overlapping the source region and the drain region of the semiconductor layer 31 in a plan view of the substrate S. In addition, in the step S38, a contact hole may be formed in a portion of the second interlayer film 36 overlapping the capacitance electrode 35 in a plan view of the substrate S by an etching method or the like. Then, a thin film containing a metal material is formed by CVD, sputtering, or the like, whereby the source electrode 38S, the drain electrode 38D, and the auxiliary capacitance electrode 38C may be formed in the step S38. Thus, the formation of the thin film transistor TR is completed in the step S38. In step S38, the source electrode layer 38 may be formed also in the frame portion NA.

Subsequently, the flattening film 39 is formed (step S39). The step S39 may be performed by applying an organic material containing a photosensitive material by a spin coating method, an ink-jet method, or the like to form a film, and then patterning the film by photolithography. In the step S39, the flattening film 39 may be formed also in the frame portion NA to thereby form a part of the first bank 61 and a part of the second bank 62. Thus, in the manufacturing method of the display device 1 according to the present embodiment, the necessity of separately providing a process of forming the bank portion 6 is reduced, and the manufacturing process is further simplified.

Thus, the process of forming the thin film transistor layer 3 is completed. Note that in at least one of the step S33, the step S35, and the step S38 in the process of forming the thin film transistor layer 3, at least a part of the dummy pattern 7 may be formed together with any of the electrodes of the thin film transistor TR. Thus, in the manufacturing method of the display device 1 according to the present embodiment, the necessity of separately providing a process of forming the dummy pattern 7 is reduced, and the manufacturing process is further simplified.

### Manufacturing Method of Display Device: Forming Light-Emitting Element Layer

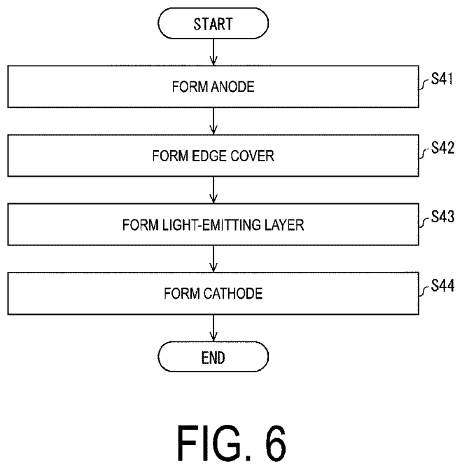

Returning to the reference of FIG. 1. subsequent to the process of forming the thin film transistor layer 3, the light-emitting element layer 4 is formed on the thin film transistor layer 3 (step S4). The process of forming the light-emitting element layer 4 will be described in more detail with reference to FIG. 6. FIG. 6 is a flowchart illustrating a process of forming the light-emitting element layer 4.

In the process of forming the light-emitting element layer 4, first, the anode 41 is formed (step S41). The step S41 may be performed by, for example, forming a thin film containing a metal material by CVD, sputtering, or the like, and then patterning the thin film on a subpixel-by-subpixel basis by etching or the like.

Subsequently, the edge cover 42 is formed (step S42). In the step S42, the organic material may be applied to form a film and the film may be patterned by the same method as the step 39. In the step S42, the edge cover 42 may be formed also in the frame portion NA to form a part of the first bank 61 and a part of the second bank 62, thereby completing the formation of the bank portion 6. In addition, the auxiliary bank portion 8 may be formed in the step S42, in other words, the process of forming the auxiliary bank portion 8 may partially overlap the process of forming the bank portion 6. Thus, in the manufacturing method of the display device 1 according to the present embodiment, the necessity of separately providing a process of forming the bank portion 6 and the auxiliary bank portion 8 is reduced, and the manufacturing process is further simplified.

Here, in the case where the organic material containing the photosensitive material is applied to form the film and the patterning is performed by photolithography in the step S42, the exposure intensity of the organic material may be changed depending on the position in a plan view of the substrate S. Accordingly, in the step S42, the height of the second bank 62 from the upper surface of the substrate S may be higher than the height of the first bank 61 from the upper surface of the substrate S. The change in the exposure intensity depending on the position in a plan view of the substrate S may be achieved by using a halftone mask as a photomask used in the exposure process. Note that in the step S42, the edge cover 42 may be formed only at the position where the second bank 62 is formed among the positions where the bank portion 6 is formed. Accordingly, in the step S42, the height of the second bank 62 from the upper surface of the substrate S can be made higher than the height of the first bank 61 from the upper surface of the substrate S by a simpler process.

Subsequently, the light-emitting layer 43 is formed (step S43). The step S43 may be performed by individually applying the light-emitting material onto each anode 41 by an ink-jet method or the like. Alternatively, the step S43 may be performed by forming and patterning a photosensitive resin layer as a sacrificing layer, then applying a light-emitting material and forming a film of the light-emitting material on the plurality of subpixels, and removing the photosensitive resin layer to pattern a thin film of the light-emitting material. The step S43 may be repeatedly executed for each luminescent color of the light-emitting layer 43.

Subsequently, the cathode 44 is formed (step S44). The step S41 may be performed by forming a thin film containing a conductive material having optical transparency by CVD, sputtering, or the like. The process of forming the light-emitting element layer 4 is completed as described above, in other words, the process of forming a plurality of light-emitting elements is completed.

Note that in the step S41 of the process of forming the light-emitting element layer 4, at least a part of the dummy pattern 7 may be formed together with the anode 41. In the case where the light-emitting element layer 4 includes the cathode 44 as a reflective electrode, at least a part of the dummy pattern 7 may be formed together with the cathode 44 in the step S44 of the process of forming the light-emitting element layer 4. Thus, in the manufacturing method of the display device 1 according to the present embodiment, the necessity of separately providing a process of forming the dummy pattern 7 is reduced, and the manufacturing process is further simplified.

### Manufacturing Method of Display Device: Forming Sealing Layer

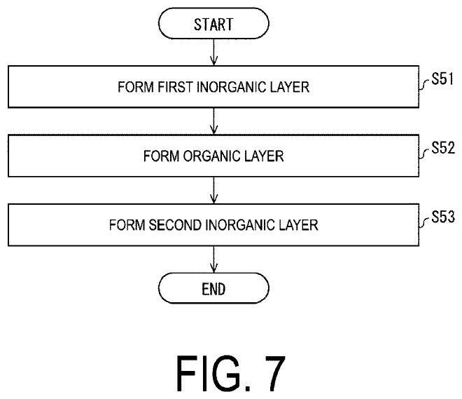

Returning to the reference of FIG. 1. subsequent to the process of forming the light-emitting element layer 4, the sealing layer 5 is formed on the light-emitting element layer 4 (step S5). The process of forming the sealing layer 5 will be described in more detail with reference to FIG. 7. FIG. 7 is a flowchart illustrating a process of forming the sealing layer 5.

In the process of forming the sealing layer 5, first, the first inorganic layer 51 is formed at a position covering the cathode 44 (step S 51). The step S 51 may be performed by forming a thin film of an inorganic material at a position covering the cathode 44 by CVD, sputtering, or the like.

Subsequently, the organic layer 52 is formed by applying an organic material to form a film of the organic material (step S52). In particular, in the step S52, the position where the organic material is applied and the amount of the organic material to be applied may be controlled so that the applied organic material stays closer to the center of the display device 1 than the bank portion 6.

Subsequently, the second inorganic layer 53 is formed by the same method as the step S51 (step S53). As described above, the process of forming the sealing layer 5 is completed, and thus the process of manufacturing the display device 1 is completed. Note that after the completion of the step S5, a touch panel film may be attached onto the sealing layer 5, or an anti-reflection film may be formed by such as bonding of a retardation film and a polarizing film onto the sealing layer 5.

### Inspection Method of Display Device

In the manufacturing method of the display device 1 according to the present embodiment, an inspection is performed to determine whether the manufactured display device 1 is a non-defective product or a defective product. An inspection method of the display device 1 according to the present embodiment will be described. Note that the inspection method of the display device 1 according to the present embodiment is performed after the organic layer 52 is formed and before an anti-reflection film or the like is formed on the sealing layer 5. In particular, the inspection method in the present embodiment is performed subsequent to the formation of the organic layer 52.

In the inspection method of the display device 1, the display portion DA and the frame portion NA of the display device 1 are irradiated with light from the display surface side of the display device 1, in other words, from the organic layer 52 side rather than the substrate S side. Here, since the dummy pattern 7 has light reflectivity, the light irradiated to the dummy pattern 7 among the light irradiated to the display device 1 is reflected, and the light can be visually recognized from the display surface side of the display device 1.

In the inspection method of the display device 1, the dummy pattern 7 is irradiated with light by the above-described method, and the light reflected by the dummy pattern 7 is analyzed. Thus, in the inspection method of the display device 1, the presence or absence of the organic layer 52, in other words, the organic material of the sealing layer 5 at the position overlapping the dummy pattern 7 in a plan view of the display device 1 is inspected.

In the present embodiment, the dummy pattern 7 is formed on the peripheral side of the display device 1 relative to the bank portion 6 in a plan view of the display device 1, particularly at a position adjacent to the bank portion 6. Therefore, when it is confirmed that the organic layer 52 is located in an upper layer of the dummy pattern 7 in the display device 1, it is confirmed that the display device 1 is a defective product in which the organic layer 52 overflows to the peripheral side relative to the bank portion 6 in a plan view.

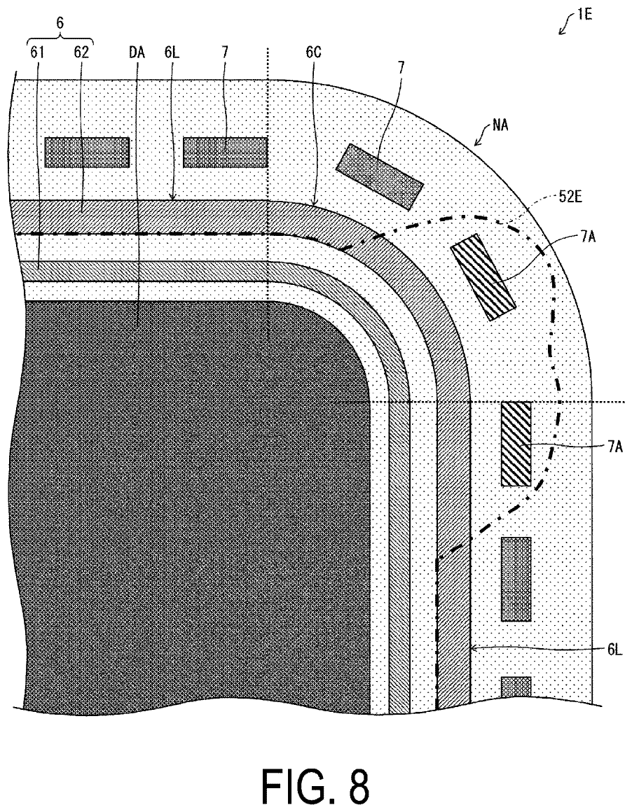

A method of determining a defect of the display device 1 described above in the inspection method of the display device 1 will be described in detail with reference to FIG. 8. FIG. 8 is an enlarged plan view of a display device 1E in which a defect occurs in the sealing layer 5, and particularly, is a view illustrating a position identical to the position illustrated in FIG. 3.

The defective display device 1E has the same configuration as the display device 1 described above except that the defective display device 1E includes a defective organic layer 52E instead of the organic layer 52. The defective organic layer 52E has the same configuration as the normal organic layer 52 except for the formation position in a plan view of the display device 1E.

For example, as indicated by the dashed-dotted line in FIG. 8, a part of the organic layer 52E is formed on the peripheral side of the display device 1E relative to the bank portion 6 in a plan view of the display device 1E. Such a defective organic layer 52E may be formed, for example, when the organic material applied in the process of forming the organic layer 52E may overflow the bank portion 6 to the peripheral side of the substrate S in a plan view. The occurrence of the defective organic layer 52E becomes more remarkable as the frame portion NA is narrowed with the increase in the definition of the display portion DA.

As illustrated in FIG. 8, a part of the dummy pattern 7 becomes a dummy pattern 7A in which the organic layer 52E is located at an overlapping position in a plan view of the display device 1E. The organic layer 52E has optical transparency, and the dummy pattern 7 has light reflectivity. Therefore, when the dummy pattern 7A is irradiated with light in the above-described inspection method, the light reflected by the dummy pattern 7A can be visually recognized.

In addition, since the organic layer 52E is located in an upper layer of the dummy pattern 7A, a part of the light irradiated to the dummy pattern 7A is also reflected on the upper surface of the organic layer 52E. Therefore, when the dummy pattern 7A is irradiated with light, the light reflected by the dummy pattern 7A and the light reflected by the upper surface of the organic layer 52E interfere with each other, that is, so-called thin-film interference occurs. Therefore, when the dummy pattern 7A is irradiated with light, the interference fringe generated by the above interference can be visually recognized in the dummy pattern 7A.

Therefore, in the above-described inspection method, the light irradiated to the dummy pattern 7 and reflected by the dummy pattern 7 is analyzed, and the presence or absence of the interference fringe in the dummy pattern 7 is inspected, whereby the presence or absence of the organic layer 52 in the upper layer of the dummy pattern 7 can be inspected. In the above-described inspection method, when there is the dummy pattern 7A in which the interference fringe can be confirmed, the display device 1E including the dummy pattern 7A may be determined to be a defective product in which the organic layer 52 is not formed at a correct position. Note that in the case where the dummy pattern 7 reflects near-infrared light or near-ultraviolet light, the light irradiated in the inspection may include near-infrared light or near-ultraviolet light, and in the inspection, the determination may be performed through measurement of the near-infrared light or near-ultraviolet light reflected by the dummy pattern 7.

In the inspection method of the display device 1 according to the present embodiment, the inspection of each light-emitting element located in the display portion DA may be performed simultaneously with the process of inspecting the presence or absence of the organic layer 52 in the upper layer of the dummy pattern 7 described above. For example, in the inspection method of the display device 1, the light-emitting layer 43 of each light-emitting element is irradiated with light by irradiating the display portion DA with light in addition to the frame portion NA. Here, when the light-emitting layer 43 is normally formed, the light-emitting material of the light-emitting layer 43 irradiated with light is photoexcited to emit light. Therefore, in the inspection method of the display device 1, the light emission intensity of each subpixel in the display portion DA is measured, whereby the defect inspection of each light-emitting element can be performed. In particular, in the inspection method of the display device 1, the entire display portion DA may be irradiated with light, and the difference in light emission intensity at each position of the display portion DA may be detected.

### Supplement

The display device 1 according to the present embodiment includes the light-reflective dummy pattern 7, and thus it is easy to irradiate the dummy pattern 7 with light and analyze the reflected light. Therefore, the display device 1 according to the present embodiment can more easily perform the inspection for determining whether or not the organic layer 52 is formed at the correct position by the above-described inspection method.

In particular, the display device 1 includes the light-reflective dummy pattern 7, and thus it is possible to further reduce the intensity of light with which the dummy pattern 7 is irradiated, which is necessary for analyzing the light reflected by the dummy pattern 7. Therefore, in the inspection method of the display device 1, it is possible to analyze the light reflected by the dummy pattern 7 by using the light irradiated to each light-emitting element of the display portion DA for the inspection of the light-emitting element. Therefore, in the inspection method of the display device 1, it is not necessary to perform an inspection of irradiation with stronger light separately from the inspection of each light-emitting element for the inspection for determining whether or not the organic layer 52 is formed at the correct position, and the entire inspection can be made simpler.

In the inspection method of the display device 1, the inspection for determining whether or not the organic layer 52 is formed at the correct position can be performed by inspecting the presence or absence of occurrence of the interference fringe in the dummy pattern 7. Therefore, in the inspection method of the display device 1, the above inspection can be performed by visually recognizing the dummy pattern 7, and thus the inspection can be performed more simply.

In a plan view of the display device 1, the distance D7 between at least a part of the dummy pattern 7 and at least a part of the bank portion 6 is 30 μm or less. Accordingly, in the display device 1, the organic layer 52 overflowing to the peripheral side from the bank portion 6 in the plan view of the display device 1 easily overlaps the dummy pattern 7 in the plan view of the display device 1. Therefore, the display device 1 further improves the accuracy of the defect determination of the sealing layer 5 by the above-described method of inspecting the formation position of the organic layer 52.

The dummy pattern 7 is formed at a position adjacent to the curved portion 6C of the bank portion 6 and the curved portion 6C side of each of the two straight portions 6L connected to the curved portion 6C. In general, the organic material applied to form the organic layer 52 tends to overflow in the vicinity of the curved portion 6C of the bank portion 6 and the boundary between the curved portion 6C and the straight portion 6L. Therefore, by providing the dummy pattern 7 at the above-described position, in the display device 1, the organic layer 52 overflowing to the peripheral side from the bank portion 6 in the plan view of the display device 1 easily overlaps the dummy pattern 7 in the plan view of the display device 1. Therefore, the display device 1 further improves the accuracy of the defect determination of the sealing layer 5 by the above-described method of inspecting the formation position of the organic layer 52.

By forming at least a part of the dummy pattern 7 in a linear shape along the bank portion 6, it is possible to reduce the detection omission in the above-described inspection method for the organic layer 52 overflowing to the upper layer of the part. Therefore, the display device 1 further improves the accuracy of the defect determination of the sealing layer 5 by the above-described method of inspecting the formation position of the organic layer 52.

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

1. A display device comprising:
a substrate;
a plurality of light-emitting elements formed on the substrate;
a bank portion formed on the substrate and surrounding the plurality of light-emitting elements;
a light-transmissive sealing layer including an organic material and covering the plurality of light-emitting elements; and
a dummy pattern having light reflectivity between the sealing layer and the substrate and on a side opposite to the plurality of light-emitting elements with respect to the bank portion.

2. The display device according to claim 1,
wherein the dummy pattern includes a metal material.

3. The display device according to claim 1,
wherein the dummy pattern is formed of a single-layer film or a multilayer film including at least one kind selected from the group consisting of Ti, Mo, Al, and Cu.

4. The display device according to claim 1,
wherein a distance between at least a part of the dummy pattern and at least a part of the bank portion is 30 μm or less in a plan view.

5. The display device according to claim 1, further comprising:
an auxiliary bank portion that is in a layer identical to at least a part of the bank portion and covers the dummy pattern.

6. The display device according to claim 1,
wherein the bank portion includes two straight portions and a curved portion connecting the two straight portions, and
the dummy pattern is adjacent to each of the curved portions and a side of the curved portion of the two straight portions.

7. The display device according to claim 1,
wherein at least a part of the dummy pattern is formed in island shapes in a plan view.

8. The display device according to claim 1,
wherein at least a part of the dummy patterns is formed linearly along the bank portion.

9. The display device according to claim 1,
wherein the light-emitting element includes two electrodes and a light-emitting layer between the two electrodes, and
the dummy pattern is in a layer identical to a layer in which one of the two electrodes is formed.

10. The display device according to claim 1, further comprising:
a thin film transistor that drives each of the light-emitting elements,
wherein the dummy pattern is in a layer identical to a layer in which any one of electrodes of the thin film transistor is formed.

11. The display device according to claim 1,
wherein the sealing layer includes a first inorganic layer including an inorganic material, a second inorganic layer that is an upper layer of the first inorganic layer and includes an inorganic material, and an organic layer that is located between the first inorganic layer and the second inorganic layer and includes the organic material.

12. An inspection method of the display device according to claim 1, comprising:
inspecting a presence or absence of the organic material at a position overlapping the dummy pattern in a plan view by irradiating the dummy pattern with light from a side of the sealing layer and analyzing light reflected by the dummy pattern.

13. The inspection method of the display device according to claim 12, further comprising:
inspecting the plurality of light-emitting elements by irradiating the plurality of light-emitting elements with light from a side of the sealing layer and measuring an intensity of light from each of the light-emitting elements,
wherein the inspecting a presence or absence of the organic material and the inspecting the plurality of light-emitting elements are performed simultaneously.

14. The inspection method of the display device according to claim 12,
wherein in the inspecting a presence or absence of the organic material, a presence or absence of occurrence of an interference fringe due to light reflected by the dummy pattern is inspected.

15. A manufacturing method of a display device comprising:
preparing a substrate;
forming a dummy pattern having light reflectivity on the substrate;
after the dummy pattern is formed, forming a plurality of light-emitting elements on the substrate and forming a bank portion surrounding the plurality of light-emitting elements; and
after the plurality of light-emitting elements and the bank portion are formed, forming a light-transmissive sealing layer covering the light-emitting elements,
wherein the forming the sealing layer includes applying an organic material.

16. The manufacturing method of a display device according to claim 15, further comprising:
forming an auxiliary bank portion covering the dummy pattern,
wherein the forming the bank portion and the forming the auxiliary bank portion at least partially overlap each other.

17. The manufacturing method of a display device according to claim 15,
wherein the forming the plurality of light-emitting elements includes forming a first electrode, forming a light-emitting layer on the first electrode, and forming a second electrode on the light-emitting layer, and
the forming the first electrode or the forming the second electrode and the forming the dummy pattern are performed simultaneously.

18. The manufacturing method of a display device according to claim 15, further comprising:
forming a thin film transistor that drives each of the light-emitting elements,
wherein the formation of any one of electrodes of the thin film transistor and the formation of the dummy pattern are performed simultaneously.
